(19) United States
(12) Patent Application Publication
(10) Pub. No.: US 2003/0044695 A1
(43) Pub. Date: Mar. 6, 2003

(54) Attenuating phase shift mask for photolithography

(76) Inventors: Mordechai Rothschild, Newton, MA (US); Vladimir Liberman, Reading, MA (US)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/020,047

(22) Filed: Dec. 7, 2001

Related U.S. Application Data
(60) Provisional application No. 60/317,694, filed on Sep. 6, 2001.

(51) Int. Cl. G03F 9/00; G03C 5/00

(52) U.S. Cl. 430/5; 430/322; 430/323; 430/324; 430/311

(57) ABSTRACT

A bilayer attenuating phase shift mask for use in photolithography having a phase shift layer and a layer of native oxide-free, elemental metal layer disposed on a substrate. The native oxide-free layer is chosen from platinum, palladium or a metal having like properties. A method of fabrication of the bilayer that uses the same etching ion to perform ion mill etching of the metal layer and chemical etching phase shift layer.

### RELATED APPLICATIONS

This application claims priority from U.S. provisional application 60/317,694 to Rothschild, et al., filed Sep. 6, 2001, entitled, “Attenuating Phase Shift Masks for Photolithography,” the subject matter of which is incorporated herein by reference.

This invention was made with government support under contract no. F 1962-800-C-0002. The government has certain rights in the invention.

### BACKGROUND OF THE INVENTION

1. Field of Invention

This invention relates to photolithographic masks, and more particularly to attenuating phase shift photolithographic masks.

2. Background

Advanced photolithographies employ a number of resolution enhancement techniques (RETs). One such enhancement technique at the mask level replaces the standard binary mask utilizing transparent areas and opaque (e.g., chrome) areas, with a mask having transparent areas and partially transparent attenuator areas that reverse the phase of transmitted light; such masks are known as attenuating phase shift masks (APSMs). The phase reversal enables destructive interference to enhance the contrast at the edges between bright and dark regions of an image of the mask produced on a wafer. This contrast enhancement results in increased depth of focus and improved resolution for printing isolated lines and contacts on a wafer. While APSMs are being inserted into 248-nm and 193-nm photolithographic systems for some applications, APSMs are critical for shorter wavelengths such as 157-nm.

For an APSM to function appropriately, it must be able to provide an appropriate attenuation and phase shift at the operational wavelength. In addition, commercially viable APSMs are preferably able to be produced using standard deposition and etching techniques, and able to withstand exposure to the operational wavelength without excessive physical or optical degradation.

Early attempts at forming suitable APSMs leveraged chrome binary mask technologies, by forming a bilayer mask having a suitably thin attenuation layer of elemental chrome and a silicon dioxide phase shift layer. Using chrome attenuation layers has presented complications because chrome readily forms an oxide upon exposure to oxygen, which changes the phase shift and attenuation characteristics of a chrome attenuation layer. To control the formation of chrome oxide, it is necessary to closely control the deposition conditions used to form the attenuation layer. Additionally, because chrome and chrome oxide have a very low transmissivity for deep-ultraviolet light (e.g., 248, 193, 157 nm), very thin layers of chrome and chrome oxide must be achieved. As a result of these complications, the optical properties of the chrome layer have proven difficult to reproduce in a controlled fashion.

To overcome the shortcomings of elemental chrome APSMs, numerous materials have been attempted for use in APSMs, and in particular for use with deep-ultraviolet light. A variety of composite materials have been suggested, such as chromium oxynitride or molybdenum silicide. Composites have been deposited to form single layer, bilayer, and multilayer APSM structures.

While composites have been able to meet some of the functional demands of APSMs, the stoichiometry of the composite must be fine-tuned to meet transmission and phase shift requirements simultaneously. Additionally, composite APSMs tend to undergo subtle chemical changes e.g., thermo-chemical effects, and microscopic physical defects resulting from environmental conditions and laser irradiation conditions under which the photolithographic process occurs. These changes are more prevalent at shorter wavelengths, such as 157 nm. While multilayer composite structures have enabled more variations in optical properties, the availability of variations is at the expense of further deposition complexity and increased sensitivity to laser damage.

### SUMMARY OF THE INVENTION

Aspects of the invention include methods and apparatuses applying a recognition that successful APSM materials preferably meet several criteria: a) a simplified ability to control phase and intensity of transmitted light; b) sufficient ease of fabrication and patterning, including compatibility with present mask making processes, c) environmental stability, d) durability under laser irradiation at the operational wavelength, and e) good electrical conductivity to dissipate electrostatic charge.

Accordingly, exemplary aspects of APSMs according to the present invention include stacks having no composite layers. Other exemplary aspects of the present invention include an elemental metal attenuation layer that does not form a native oxide; therefore, selection and deposition of the attenuation layer thickness and the phase shift layer thickness necessary to achieve a selected attenuation and phase shift is facilitated.

A first aspect of the invention is a photolithographic mask to transmit light, comprising a transparent substrate, a native oxide-free, elemental metal, first layer to attenuate the light, and a second layer to impart a phase delay on the light. One of the first layer and the second layer is disposed on the substrate, and the other of the first layer and the second layer is disposed on the one of the first layer and the second layer. Preferably, the first layer is substantially amorphous. In one embodiment, the first layer is platinum. In another embodiment, the first layer is paladium. In some embodiments, the first layer and the second layer combine to impart a phase delay of one-half of a wavelength of the light. Preferably, the second layer is a substantially carbon-free spin-on glass. In one embodiment, the second layer is Hydroxy Silsesquioxane.

A second aspect of the invention is a photolithographic mask to transmit light, comprising a transparent substrate, a platinum first layer to attenuate the light, and a second layer to impart a phase delay on the light. One of the first layer and the second layer is disposed on the substrate, and the other of the first layer and the second layer is disposed on the one of the first layer and the second layer.

A third aspect of the invention is a method for forming a photolithographic mask to transmit light comprising the steps of (a) providing a transparent substrate, (b) depositing a native oxide-free, elemental metal, first layer, and (c) depositing a second layer upon the first layer. One of the first layer and the second layer is disposed on the substrate, and the other of the first layer and the second layer is disposed on the one of the first layer and the second layer, the first layer attenuating the light, and the second layer imparting a phase delay on the light. In one embodiment, the first layer is platinum. In another embodiment, the first layer is paladium. Optionally, the method may further comprise chemically etching the second layer, and ion milling the first layer. Preferably, the chemical etching and ion milling steps are performed using the same ions. In one embodiment, the ion milling and chemical etching are performed using CH₃ ions. Preferably, the chemical etching and ion milling occur in the same processing chamber of an ion processing apparatus. Optionally, the ion milling is performed using argon ions.

A fourth aspect of the invention is a photolithographic system comprising an at least partially coherent light source to produce light; and a photolithographic mask to transmit the light, comprising a transparent substrate, a native oxide-free, elemental metal, first layer, and a second layer to impart a phase delay on the light. One of the first layer and the second layer is disposed on the substrate, and the other of the first layer and the second layer is disposed on the one of the first layer and the second layer.

### BRIEF DESCRIPTION OF THE DRAWINGS

Illustrative, non-limiting embodiments of the present invention will be described by way of example with reference to the accompanying drawings, in which the same reference numeral is used for common elements in the various figures, and in which:

FIG. 1 is a cross-sectional side view of a bilayer stack according to the present invention;

FIG. 2 is a cross-sectional side view of one example of an embodiment of a patterned photolithographic mask according to the present invention;

FIG. 3 is a schematic illustrating an example of one embodiment of a photolithographic system employing a mask made according to the present invention;

FIGS. 4a-4c are graphical representations of attenuation and phase delay as a function of platinum layer thickness, for exemplary wavelengths of light;

FIG. 5a is a flow chart illustrating an exemplary fabrication process to form a stack or mask according to the present invention, wherein a native-oxide free metallic layer is disposed on a substrate; and

FIG. 5b is a flow chart illustrating an exemplary fabrication process to form a stack or mask according to the present invention, wherein a phase shift layer is disposed on a substrate.

### DETAILED DESCRIPTION OF THE INVENTION

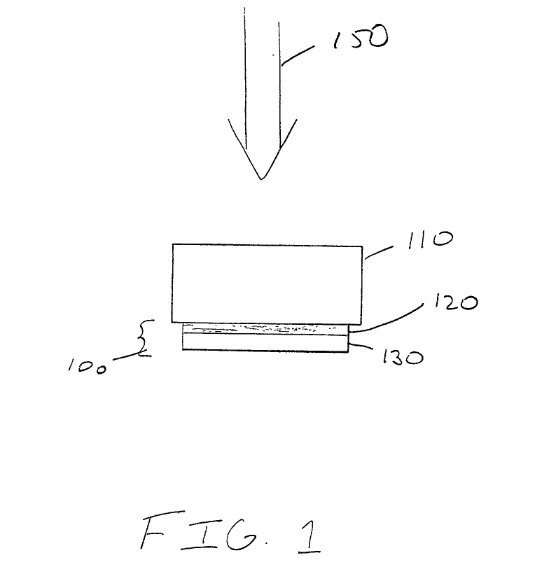

FIG. 1 is a cross-sectional side view of a bilayer stack 100 according to the present invention. A stack, such as stack 100, is also referred to as an unpatterned photolithographic mask or a photolithographic mask blank. As used hereinunder the term “mask” is intended to include both photolithographic mask blanks, and patterned masks.

Stack 100 is deposited on substrate 110. Substrate 110 may for example be a standard fused SiO₂ mask substrate. For stacks to be used with light having a wavelength of 157 nm, substrate 110 is constructed of any known mask material that transmits light having a wavelength of 157 nm (e.g., modified fused-silica).

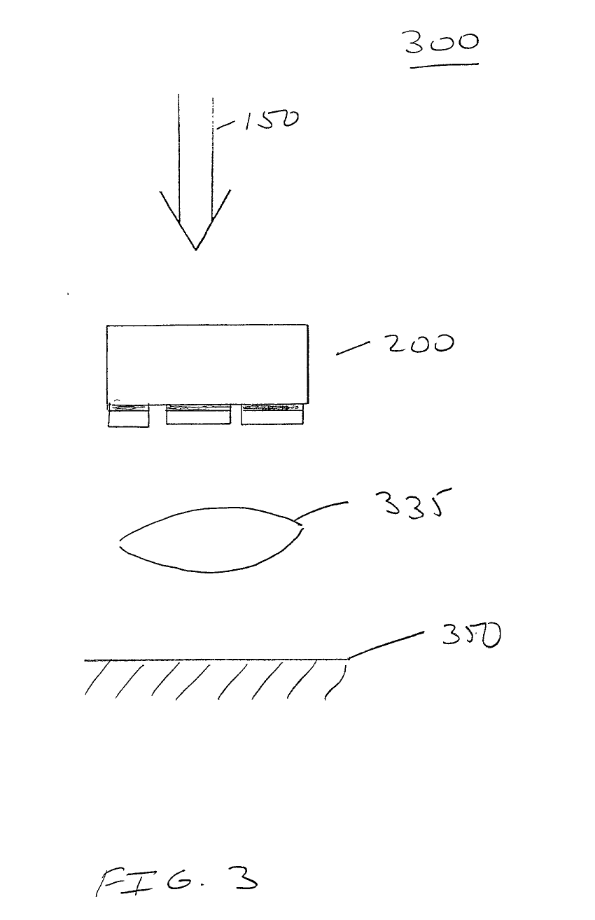

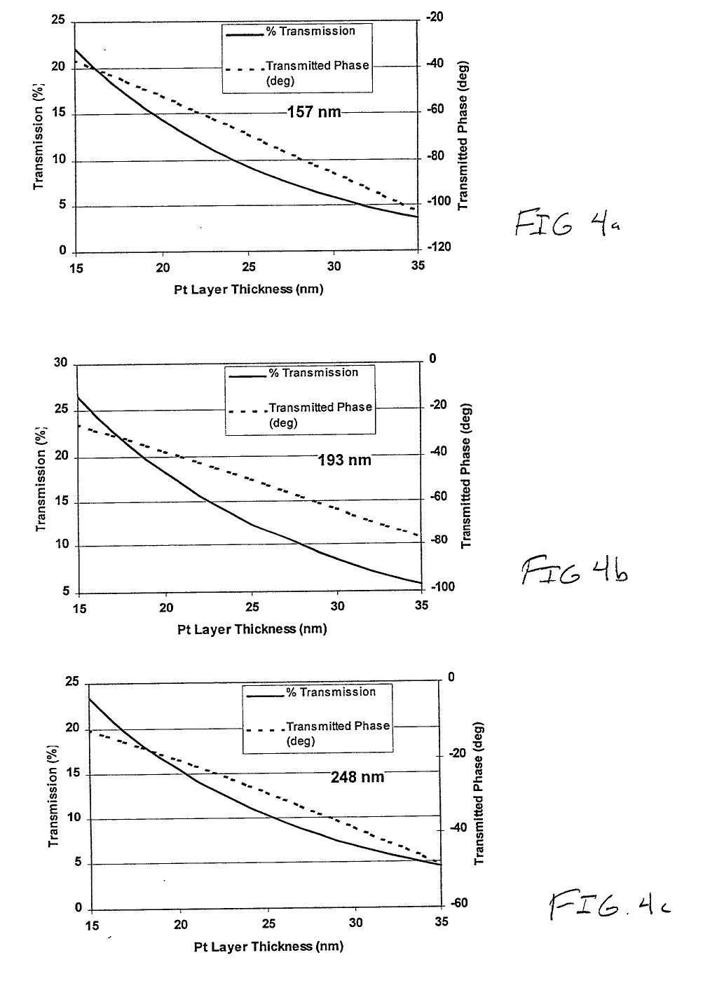

Layer 120 (also referred to as an “attenuation layer”) disposed on substrate 110 is a film that provides light attenuation for light 150 projected through stack 100. The thickness of layer 120 is selected to achieve a given light attenuation. As one of ordinary skill in the art would understand, the desired attenuation provided by layer 120 depends on factors such as the sizes and shapes of the features on the mask to be formed from the stack, and the characteristics of the photolithographic system with which the mask so formed is to be used (e.g., the numerical aperture of the projection system 335 in FIG. 3). As described in greater detail below with reference to FIGS. 4a-4c, the thickness of layer 120 necessary to achieve a given attenuation depends on a number of factors, including the wavelength of light 150, the material used for construction of layer 120, and the deposition process used to deposit layer 120.

In accordance with the principles of the present invention, layer 120 is an elemental metal that does not develop a native oxide (i.e., the layer is a native oxide-free elemental metal). An attenuation layer formed of a metal that is native oxide-free allows the attenuation of light 150 to be controlled to a higher degree than an attenuation layer formed of a material that is native oxide-forming, because attenuation by a native oxide is dependent on factors such as temperature, humidity, and the deposition method used to deposit the attenuation layer. Additionally, a native oxide may introduce a phase shift on light 150 that is dependent on similar factors.

Preferably, layer 120 is a material that can be deposited reliably for precise control of transmitted light intensity, and is compatible with present mask making processes. Particularly useful materials for construction of layer 120 are chemically stable when exposed to coherent or partially coherent light having a wavelength of 248 nm or less. In one embodiment of the invention, layer 120 is substantially electrically conductive and preferably highly electrically conductive (i.e., having a metal-like conductivity) to dissipate electrostatic charge that may develop on the mask. In another embodiment of the invention, layer 120 has a fine grain (i.e., no structure is visible when viewed with 1×10⁶ magnification); such a structure is also referred to as substantially amorphous. In a preferred embodiment of bilayer stack 100, layer 120 is a layer of platinum (Pt). In other embodiments, layer 120 is a layer of palladium (Pd) or another metal having like properties. As discussed with reference to FIG. 4a below, one example of a layer 120 for use with light of approximately 157 nm is a layer of platinum having a thickness of approximately 28 nm which can be used to achieve a transmission of approximately 7%.

Layer 130 (also referred to as a “phase delay layer”) disposed on layer 120 is a transparent material capable of altering the phase of light transmitted through it. Preferably, layer 130 is a glass that is transparent at wavelengths below 248 nm. In one embodiment, layer 130 is a spin-on glass transparent at wavelengths below 248 nm. Particularly useful materials for use in layer 130 are substantially carbon-free. Materials appropriate for forming layer 130 include Hydroxy Silsesquioxane (SiOₓ; where x is less than 2). One example of a spin-on glass appropriate for forming layer 130 is FOX-11, manufactured by Dow Coming Corporation, which when cured at 400° C. for about 1 hour has indices of refraction of n=1.685 at 157 nm, 1.516 at 193 nm and 1.456 at 248 nm. The cure time is selected to solidify layer 130 and to remove residual carbon from layer 130, such that there is negligible absorption of light having a wavelength of 157 nm or longer. In one embodiment, the thickness of layer 130 is selected so that the combined phase delay imparted by layer 130 and layer 120 is equal to one-half of a wavelength of light 150.

As described in greater detail with reference to FIGS. 4a-4c, although attenuation layer 120 is selected to achieve a given attenuation, attenuation layer 120 does impart a phase delay on light 150. Accordingly, when selecting the thickness of layer 130 to achieve the desired phase delay, the phase delay imparted by layer 120 must be considered. However, layer 130 provides negligible attenuation of light 150. Accordingly, the thickness of layer 120 controls the attenuation of stack 100 independent of layer 130

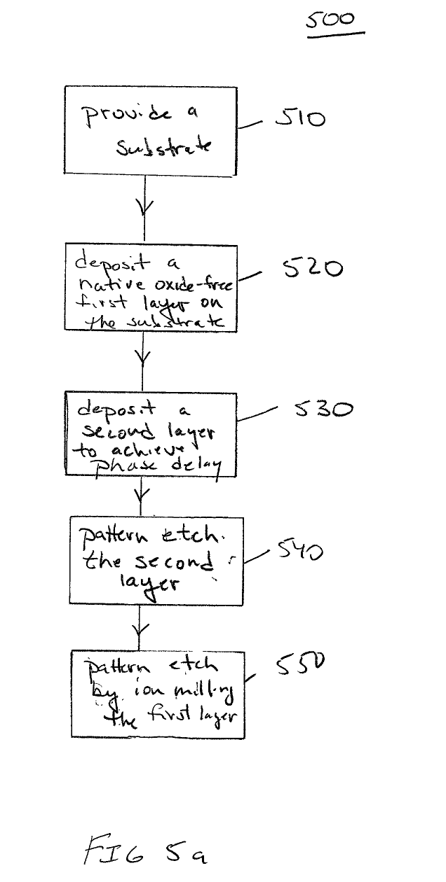

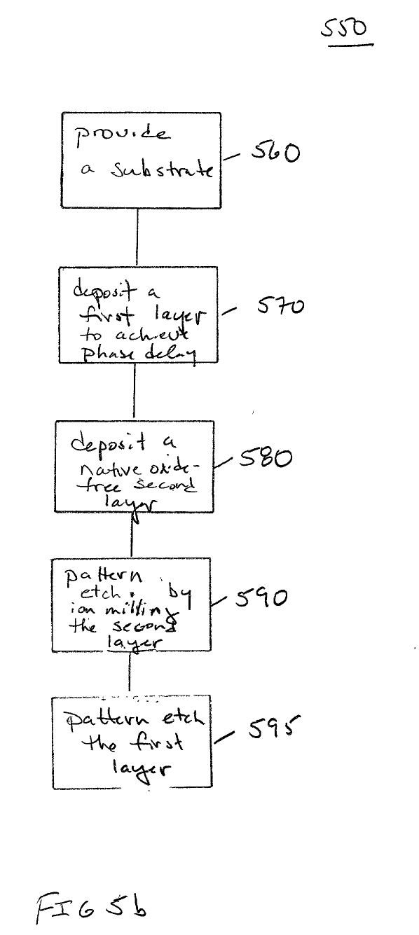

While stacks made according to the present invention have a reduced susceptibility to damage at longer wavelengths, it is significant that no laser-induced changes in bilayer stack 100 were observed during prolonged exposure to 157 nm laser radiation. It should be understood that while the above embodiment of the invention has layer 120 disposed on substrate 110 and an outer layer 130 disposed on layer 120, embodiments having layer 130 disposed on substrate 110 and layer 120 disposed on layer 130 are within the scope of this invention. As described below with reference to FIGS. 5a and 5b, each embodiment has fabrication advantages.

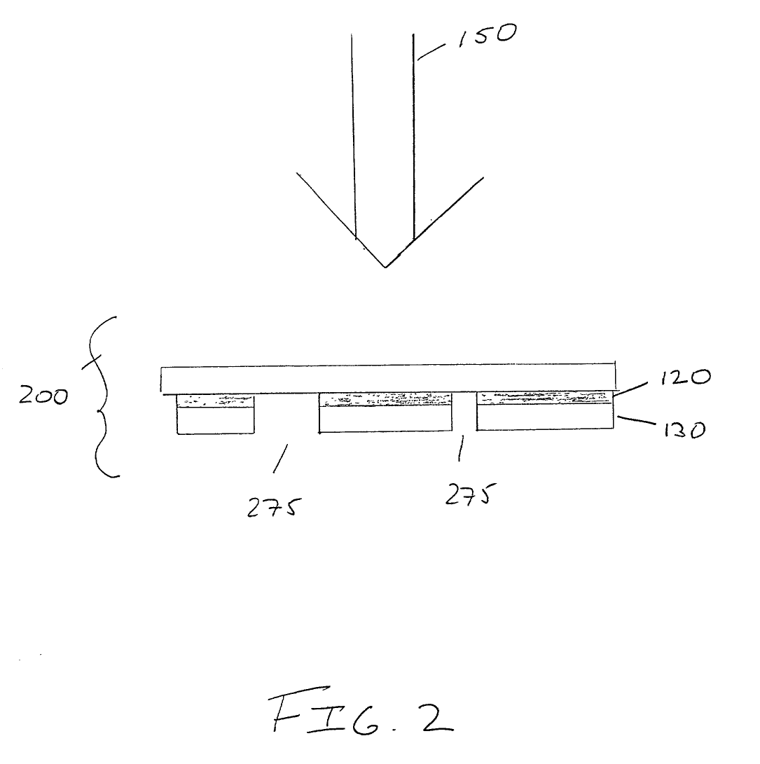

FIG. 2 is a cross-sectional side view of one example of an embodiment of a photolithographic mask 200 according to the present invention. Mask 200 has been patterned for use in photolithography, such that bilayer structures having layers 120 and 130 are located adjacent to exemplary openings 275. Accordingly, for light projected onto mask 200, layers 120 and 130 impart a phase delay on at least a portion of the light transmitted by mask 200. The shape and size of openings 275 corresponds to features to be created using mask 200. Typically, the bilayer structure of a mask covers substrate 110 at substantially all locations except at openings 275.

FIG. 3 is a schematic illustrating an example of one embodiment of a photolithographic system 300 employing a mask 200 made according to the present invention. A coherent or partially coherent light source 150 is used having a selected wavelength, e.g., 157 nm, 193 nm and 248 nm and having a selected illumination pattern, including but not limited to a ring, a disk or a multi-lobed pattern of desired size. Mask 200 is imaged onto a target wafer 350 thus forming regions of illumination having reduced illumination strength due to destructive interference. Projection system 335 may be a known projection system such as a lens system having one or more lens elements.

FIGS. 4a-4c are graphical representations of attenuation and phase delay as a function of attenuation layer thickness, for exemplary wavelengths of light. The graphical representations correspond to attenuation layers of platinum deposited by ion beam sputterer from the VCR Group Inc., model number IBS/TM200S. FIGS. 4a, 4b, and 4c are graphical representations of attenuation and phase delay, as a function of platinum layer thickness, wherein the light has a wavelength of 157 nm, 193 nm, and 248 nm respectively.

The graphical representations of FIGS. 4a-4c are useful for selecting the thickness of a platinum attenuation layer that is necessary for achieving a given attenuation for a bilayer stack. After selecting a platinum attenuation layer thickness, by using the graphical representation to determine the phase delay associated with the platinum attenuation layer thickness, it is possible to determine the thickness of the phase delay layer (having a known index of refraction) that is necessary to achieve a selected phase delay for the bilayer stack.

One aspect of a bilayer stack (or mask) according to the present invention is its simplicity of fabrication and patterning. FIG. 5a is a flow chart illustrating an exemplary, simplified fabrication process 500 to form a stack or mask according to the present invention, wherein a native oxide-free metallic layer is disposed on a substrate. The fabrication process discussed is not intended to limit the fabrication technologies that can be employed to produce a stack or mask according to the present invention.

At step 510, a substrate is provided. At step 520, a native oxide-free metallic first layer is deposited on the substrate by a vacuum deposition. To achieve a fine grain structure, a high vacuum is preferred. For example, the baseline pressure (i.e., pressure before the deposition takes place) is in the mid-10⁻⁶ Torr range, and during the deposition, the pressure may rise to mid-10⁻⁵ Torr. As described above, an appropriate thickness for the first layer is selected to achieve an appropriate attenuation, dependent on the qualities of light to be transmitted and the selected application for stack or mask so formed. At step 530, a second layer can then be deposited with appropriate thickness uniformity and having a thickness to achieve a desired phase delay, e.g., using standard solvents and spin-on technology.

At step 540, the stack formed according to steps 510, 520, and 530 is pattern etched (e.g., using any known photoresist or electron beam resist) to form a photolithographic mask, by using a standard oxide reactive-ion chemical etch to form openings in the second layer; advantageously, the underlying first layer acts as a natural etch stop. An appropriate etchant is CHF₃. At step 550, first layer (˜250 Angstroms) is etched by ion-milling, for example, using Argon ion or CHF₃ ion milling at an energy of 100-500 V to form an opening in the first layer and form an appropriate mask pattern. By timing the ion milling step appropriately, no roughening of the substrate is observed. Following milling of the first layer, the photoresist is removed. The above process is scalable for use with large and small area stacks.

To determine an appropriate ion milling duration for a set of milling conditions, several test stacks can be exposed to milling for different durations. An appropriate duration can be determined by measuring the amount of milling occurring on each test stack, e.g., using a standard mechanical surface-profilometer.

In one embodiment, the chemical etchant and ion milling etchant compounds are both selected to be CHF₃. Accordingly, it is possible to perform the patterning of both the first layer and the second layer in a single processing chamber of an ion processing apparatus, thus reducing time and cost of production. The chemical etching is performed at a relatively low energy setting of the apparatus, and the ion milling is performed at a relatively high energy setting of the same apparatus.

FIG. 5b is a flow chart illustrating a second exemplary simplified fabrication process 550 to form a stack or mask according to the present invention, wherein a phase delay layer is disposed on a substrate. At step 560, a substrate is provided. At step 570, a first layer (i.e., a phase delay layer) is then be deposited with appropriate thickness uniformity and having a thickness to achieve a desired phase delay, e.g., using standard solvents and spin-on technology. Embodiments of the invention wherein the phase shift layer is disposed on the substrate may provide benefits with some deposition methods because the phase shift layer has a similar chemical composition to the substrate, and therefore may be more adhesive to the substrate than a metal layer deposited directly on the substrate.

At step 580, a native oxide-free metallic second layer is deposited on the substrate by a vacuum deposition. To achieve a fine grain structure, a high vacuum is preferred. For example, the baseline pressure is in the mid-10⁻⁶ Torr range. As described above, an appropriate thickness for the second layer is selected to achieve an appropriate attenuation, dependent on the qualities of light to be transmitted and the selected application for stack or mask so formed.

At step 590, the native oxide-free metallic second layer (˜250 Angstroms) is pattern etched (e.g., using any known photoresist or electron beam resist) by ion-milling. For example, Argon ion or CHF₃ ion milling at an energy of 100-500 V may be used to form an opening in the second layer. By timing the ion etching step appropriately, no milling of the first layer is observed. At step 595, the first layer is chemically etched by using a standard oxide reactive-ion etch to form openings in the first layer. Following the etch of the first layer, the photoresist is removed.

Because a metallic layer does not separate the phase delay layer from the substrate, unlike the embodiment discussed above, the metal layer does not act as a stop and the etchant used to chemically etch the phase delay layer may etch the substrate. Accordingly, as one of ordinary skill in the art would understand, in embodiments of the present invention where the phase delay layer is disposed on the substrate, the etch of the phase shift layer must be timed to prevent etching of the substrate. An appropriate etchant is CHF₃.

In one embodiment, the chemical etchant and ion milling etchant compounds are both selected to be CHF₃. Accordingly it is possible to perform the patterning of both the first layer and the second layer in a single processing chamber of an ion processing apparatus, thus reducing time and cost of production. The chemical etching is performed at a relatively low energy setting of the apparatus, and the ion milling is performed at a relatively high energy setting of the same apparatus.

While stacks developed according to the present invention are useful for longer wavelengths, they are particularly appropriate for use with photolithographic systems using short wavelengths of light, for example 157 nm, 193 nm, and 248 nm. The design can be used to provide APSMs with varying transmissions tuned for specific geometries, mask topographies, and photolithographic systems by selecting the thickness of the first layer and the second layer to achieve a desired attenuation and phase shift.

Having thus described the inventive concepts and a number of exemplary embodiments, it will be apparent to those skilled in the art that the invention may be implemented in various ways, and that modifications and improvements will readily occur to such persons. Thus, the examples given are not intended to be limiting, and are provided by way of example only. The invention is limited only as required by the following claims and equivalents thereto.

What is claimed is:

1. A photolithographic mask to transmit light, comprising:
a transparent substrate;
a native oxide-free, elemental metal, first layer to attenuate the light; and
a second layer to impart a phase delay on the light, one of the first layer and the second layer disposed on the substrate, and the other of the first layer and the second layer disposed on the one of the first layer and the second layer.

2. The photolithographic mask of claim 1, wherein the first layer is substantially amorphous.

3. The photolithographic mask of claim 1, wherein the light is at least partially coherent light and has a wavelength of less than 248 nm.

4. The photolithographic mask of claim 1, wherein the first layer is platinum.

5. The photolithographic mask of claim 1, wherein the first layer is paladium.

6. The photolithographic mask of claim 1, wherein the first layer and the second layer combine to impart a phase delay of one-half of a wavelength of the light.

7. The photolithographic mask of claim 1, wherein the second layer is a spin-on glass.

8. The photolithographic mask of claim 7, wherein the second layer is a substantially carbon-free material.

9. The photolithographic mask of claim 8, wherein the second layer is Hydroxy Silsesquioxane.

10. The photolithographic mask of claim 1, wherein the first layer is disposed on the substrate.

11. A photolithographic mask to transmit light, comprising:
a transparent substrate;
a platinum first layer to attenuate the light; and
a second layer to impart a phase delay on the light, one of the first layer and the second layer disposed on the substrate, and the other of the first layer and the second layer disposed on the one of the first layer and the second layer.

12. The photolithographic mask of claim 11, wherein the first layer is substantially amorphous.

13. The photolithographic mask of claim 11, wherein the first layer and the second layer combine to impart a phase delay of one-half of a wavelength of the light.

14. The photolithographic mask of claim 11, wherein the second layer is a spin-on glass.

15. The photolithographic mask of claim 14, wherein the second layer is a substantially carbon-free material.

16. The photolithographic mask of claim 15, wherein the second layer is Hydroxy Silsesquioxane.

17. The photolithographic mask of claim 11, wherein the first layer is disposed on the substrate.

18. A method for forming a photolithographic mask to transmit light, comprising:
providing a transparent substrate;
depositing a native oxide-free, elemental metal, first layer; and
depositing a second layer upon the first layer, one of the first layer and the second layer disposed on the substrate, and the other of the first layer and the second layer disposed on the one of the first layer and the second layer, wherein the first layer attenuates the light, and wherein the second layer imparts a phase delay on the light.

19. The method for forming photolithographic mask of claim 18, wherein the first layer is platinum.

20. The method for forming photolithographic mask of claim 18, wherein the first layer is paladium.

21. The method for forming photolithographic mask of claim 18, further comprising chemically etching the second layer.

22. The method for forming photolithographic mask of claim 19, further comprising ion milling the first layer.

23. The method for forming photolithographic mask of claim 22, wherein the chemical etching and ion milling steps are performed using the same ions.

24. The method for forming photolithographic mask of claim 23, wherein the ion milling and chemical etching are performed using CH₃ ions.

25. The method for forming photolithographic mask of claim 22, wherein the ion milling is performed using argon ions.

26. The method for forming photolithographic mask of claim 24, wherein the chemical etching and ion milling occur in the same processing chamber of an ion processing apparatus.

27. The method for forming photolithographic mask of claim 18, wherein the first layer is disposed on the substrate.

28. A photolithographic system, comprising:
an at least partially coherent light source to produce light; and
a photolithographic mask to transmit the light, comprising a transparent substrate, a native oxide-free, elemental metal, first layer, and a second layer to impart a phase delay on the light, one of the first layer and the second layer disposed on the substrate, and the other of the first layer and the second layer disposed on the one of the first layer and the second layer.

29. The photolithographic system of claim 28, wherein the light is at least partially coherent light and has a wavelength of less than 248 nm.

30. The photolithographic system of claim 28, wherein the first layer is substantially amorphous.

31. The photolithographic system of claim 28, wherein the first layer is platinum.

32. The photolithographic system of claim 28, wherein the first layer is paladium.

33. The photolithographic system of claim 28, wherein the first layer and the second layer combine to impart a phase delay of one-half of the wavelength of the light.

34. The photolithographic system of claim 28, wherein the second layer is a spin-on glass.

35. The photolithographic system of claim 34, wherein the second layer is a substantially carbon-free material.

36. The photolithographic system of claim 35, wherein the second layer is Hydroxy Silsesquioxane.

37. The photolithographic system of claim 35, wherein the first layer is disposed on the substrate.
